(19) United States
(12) Patent Application Publication
(10) Pub. No.: US 2023/0369414 A1
(43) Pub. Date: Nov. 16, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventors: Atsushi SAKAI, Tokyo (JP); Katsumi EIKYU, Tokyo (JP); Yasuhiro OKAMOTO, Tokyo (JP); Kenichi HISADA, Tokyo (JP); Nobuo MACHIDA, Tokyo (JP)

(21) Appl. No.: 18/358,474

(22) Filed: Jul. 25, 2023

Related U.S. Application Data
(62) Division of application No. 16/996,351, filed on Aug. 18, 2020.

(30) Foreign Application Priority Data
Sep. 6, 2019 (JP) 2019-163053

(51) Int. Cl. H01L 29/16; H01L 29/66; H01L 29/78

(52) U.S. Cl. CPC H01L 29/1608; H01L 29/66734; H01L 29/7813

(57) ABSTRACT

Semiconductor device has a cell region and a peripheral region, and has a drift layer, a trench, an gate dielectric film on an inner wall of the trench, a gate electrode, and a p-type first semiconductor region below the trench in the cell region on a semiconductor substrate. Further, in the peripheral region on the semiconductor substrate, p-type second semiconductor region is formed in the same layer as the p-type first semiconductor region. a width of the p-type first semiconductor region and a width of the p-type second semiconductor region are different.

### CROSS-REFERENCE TO RELATED APPLICATIONS

This is Divisional of U.S. patent application Ser. No. 16/996,351 filed on Aug. 18, 2020, which claims the benefit of Japanese Patent Application No. 2019-163053 filed on Sep. 6, 2019, including the specification, drawings and abstract are incorporated herein by reference in their entirety.

### BACKGROUND

The present invention relates to a semiconductor device and method of manufacturing the same, for example, semiconductor device and method of manufacturing the same relates to using SiC (silicon carbide) substrate.

Semiconductor device using SiC substrate has been studied in semiconductor device with transistors. For example, when using SiC substrate in the power transistor, since the band gap of SiC is large compared with Si (silicon), it is possible to improve the trade-off relationship between on-resistance and withstand voltage.

Japanese Patent Laid-Open No. JP-A-2014-138026 (Patent Document 1) has an n-type source layer, a p-type base layer, an n-type base layer, a p-type buried layer, and a drain electrode. In semiconductor device, when the off-state, in proportion to an increase in the applied voltage, the depletion layer expands from the p-type base layer to the drain electrode side. When the depletion layer reaches the p-type buried layer, a punch-through phenomenon occurs. Thus, p-type buried layer by fixing the electric field strength in the depletion layer, it is disclosed that the increase in the electric field strength is suppressed. Then, to decrease the on-resistance per unit area by increasing the carrier density of the n-type base layer in a range with a limit value of the field strength exceeding the maximum value of the electric field intensity at this time. Thus, a technique for reducing the voltage drop in the on-state even high withstand voltage is disclosed.

Japanese Patent Laid-Open No. JP-A-9-191109 (Patent Document 2) discloses a semiconductor device having a cell region in which a MISFET is formed and a peripheral region formed outside the cell region. The MISFET is composed of a laminated film in which semiconductor substrate, a first epitaxial film, and a second epitaxial film are laminated in this order. The first epitaxial film has a first relaxation region formed at an interface between semiconductor substrate and the first epitaxial film, and a second relaxation region formed at an interface between the first epitaxial film and the second epitaxial film. As a result, a technique for reducing the size of MISFET while increasing the withstand voltage is disclosed.

### SUMMARY

As described above, since the band gap of SiC is large compared with Si, it is possible to improve the trade-off relationship between on-resistance and withstand voltage. However, compared to semiconductor device with Si substrate, in semiconductor device using SiC substrate, since SiC substrate can withstand higher field strength than Si substrate, gate dielectric film breakdown is likely to occur due to field concentration. From the viewpoint of relaxation, the electric field concentration to gate dielectric film, it is known that the electric field relaxation area for electric field relaxation is provided. However, depending on the configuration of the electric field relaxation region, it may not be obtained sufficient reliability. That is, there is room for improvement from the viewpoint of enhancing the reliability of semiconductor device.

It is an object of embodiments to improve the reliability of the semiconductor device.

Other objects and novel features will become apparent from the description of this specification and the accompanying drawings.

### BRIEF DESCRIPTION OF THE DRAWINGS

FIG. 1 is a plan view of an entire chip showing an exemplary configuration of the semiconductor device according to a first embodiment.

FIG. 2 is a plan view of a main portion diagram showing an exemplary configuration of the semiconductor device according to the first embodiment.

FIG. 3 is a cross-sectional view of a main portion showing an exemplary configuration of the semiconductor device according to the first embodiment.

FIG. 4 is a cross-sectional view of a main portion showing an exemplary process included in a manufacturing method of the semiconductor device according to the first embodiment.

FIG. 5 is a cross-sectional view of a main portion showing an exemplary process included in the manufacturing method of the semiconductor device according to the first embodiment.

FIG. 6 is a cross-sectional view of a main portion showing an exemplary process included in the manufacturing method of the semiconductor device according to the first embodiment.

FIG. 7 is a cross-sectional view of a main portion showing an exemplary process included in the manufacturing method of the semiconductor device according to the first embodiment.

FIG. 8 is a cross-sectional view of a main portion showing an exemplary process included in the manufacturing method of the semiconductor device according to the first embodiment.

FIG. 9 is a cross-sectional view of a main portion showing an exemplary process included in the manufacturing method of the semiconductor device according to the first embodiment.

FIG. 10 is a cross-sectional view of a main portion showing an exemplary process included in the manufacturing method of the semiconductor device according to the first embodiment.

FIG. 11 is a cross-sectional view of a main portion showing an exemplary process included in the manufacturing method of the semiconductor device according to the first embodiment.

FIG. 12 is a cross-sectional view of a main portion showing an exemplary process included in the manufacturing method of the semiconductor device according to the first embodiment.

FIG. 13 is a plan view showing a structure of a semiconductor device of a comparative example.

FIG. 14 is a cross-sectional view showing the structure of the semiconductor device of the comparative example.

FIG. 15 is a diagram showing the relationship between a withstand voltage of the semiconductor device according to the first embodiment and a width of a p-type semiconducting region of a peripheral region.

FIG. 16 is a plan view of a main portion diagram showing an exemplary configuration of a semiconductor device according to a second embodiment.

FIG. 17 is a cross-sectional view in A-A line shown in FIG. 16 showing an exemplary configuration of the semiconductor device according to the second embodiment.

FIG. 18 is a cross-sectional view in B-B line shown in FIG. 16 showing an exemplary configuration of the semiconductor device according to the second embodiment.

FIG. 19 is a diagram showing a relationship between a withstand voltage of the semiconductor device according to the second embodiment and the width of the p-type semiconducting region of the peripheral region.

FIG. 20 is a plan view of a main portion diagram showing an exemplary configuration of the semiconductor device according to a modified example of the first embodiment.

FIG. 21 is a cross-sectional view in A-A line shown in FIG. 20 illustrating an exemplary configuration of the semiconductor device according to the modified example of the first embodiment.

FIG. 22 is a plan view illustrating an exemplary configuration of the semiconductor device according to the modified example of the second embodiment.

FIG. 23 is a cross-sectional view in A-A line shown in FIG. 22 illustrating an exemplary configuration of the semiconductor device according to the modified example of the second embodiment.

### DETAILED DESCRIPTION

In the following embodiments, if necessary for convenience, will be described separately into several sections or embodiments, but except as specifically indicated, they are not independent of each other. Also, one may be related to some or all of the other modified example, applications, detailed descriptions, supplementary descriptions, and the like. In the following embodiments, reference to the number of elements or the like (including the number, numerical value, quantity, range, and the like) is not limited to the specific number, and may be greater than or equal to the specific number or less, except in the case where it is specifically specified and the case where it is obviously limited to the specific number in principle.

Furthermore, in the following embodiments, the constituent elements (including element steps and the like) are not necessarily essential except in the case where they are specifically specified and the case where they are considered to be obviously essential in principle. Similarly, in the following embodiments, reference to shapes, positional relationships, and the like of constituent elements and the like includes substantially approximate or similar shapes and the like, except for the case in which they are specifically specified and the case in which they are considered to be obvious in principle and the like. The same applies to the above-mentioned numbers and the like, including the number, the numerical value, the amount, the range, and the like.

In all the drawings for explaining the embodiments, members having the same function are denoted by the same or related reference numerals, and repetitive description thereof is omitted. In addition, when there are a plurality of similar members (portions), symbols may be added to the generic reference numerals to indicate individual or specific portions. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of a plan view, hatching may be used to make the drawing easier to see.

Also, in cross-sectional view and plan view, the size of each part does not correspond to the actual device. In addition, in order to make the drawing easier to understand, a specific portion may be displayed in a relatively large size in some cases. In addition, even when cross-sectional view and plan view correspond to each other, a particular portion may be displayed relatively large in order to make the drawing easy to understand.

### First Embodiment

Hereinafter, the semiconductor device according to the first embodiment will be described in detail by referring to the drawings.

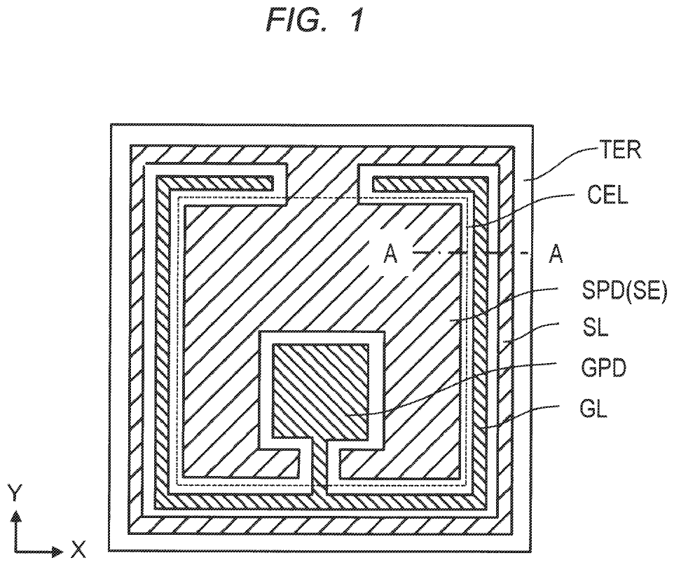

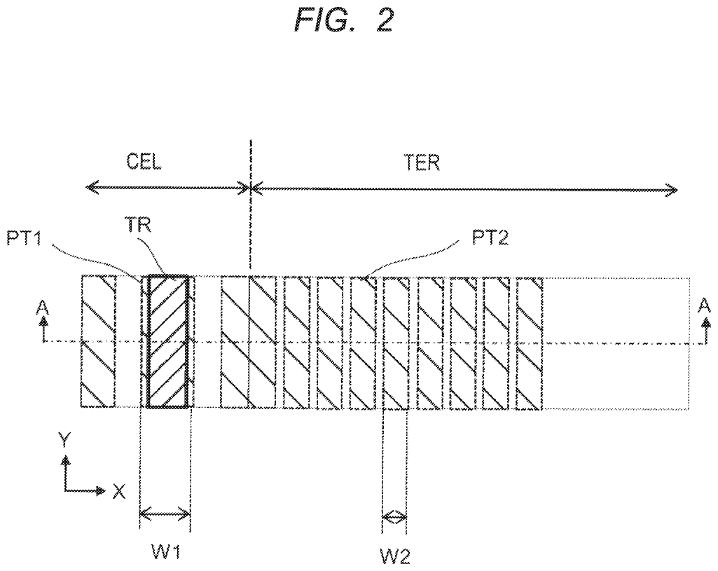

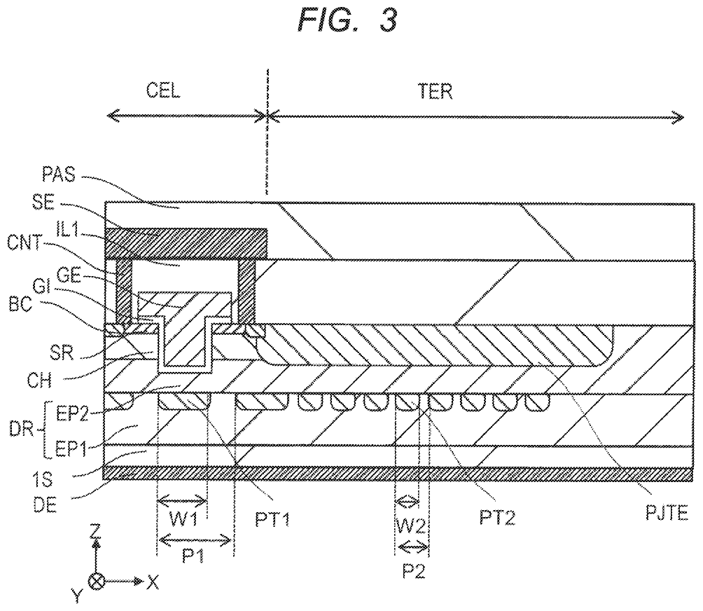

FIG. 1 is a plan view of an entire chip showing an exemplary configuration of the semiconductor device according to the first embodiment. FIGS. 2 and 3 are a plan view and a cross-sectional view of a main portion diagram in the A-A line shown in FIG. 1 showing an exemplary configuration of the semiconductor device according to the first embodiment. Further, the semiconductor device shown in FIGS. 1, 2, and 3 are a trench gate type power transistor.

As shown in FIG. 1, the semiconductor device according to the first embodiment has a cell region CEL at a center of the semiconductor device. A peripheral region TER is located outside the cell region CEL. Further, the semiconductor device according to the first embodiment has a source pad SPD (a source electrode SE) and a gate pad GPD on a top surface of the chip, a drain pad on a bottom surface of the chip (a drain electrode DE) (not shown).

FIG. 2 is a plan view showing the relationship between a trench TR of a configuration of the semiconductor device according to the first embodiment and a p-type semiconductor region (field relaxation region), FIG. 3 corresponds to the cross-sectional portion in A-A line of FIG. 2.

The semiconductor device according to the first embodiment has a SiC substrate 1S, an n-type drift layer DR, a channel layer CH, an n-type source region SR, the trench TR, a gate dielectric film GI, a gate electrode GE, an interlayer insulating film IL1, a body contact region BC, a contact hole CNT, the source electrode SE, a surface protective film PAS, the drain electrode DE, a p-type buried region PJTE, a p-type first semiconductor region PT1 and a p-type second semiconductor region PT2.

First, as shown in FIG. 3, the semiconductor device according to the first embodiment has the cell region CEL and the peripheral region TER at its outer peripheral portion. The cell region CEL has a drift layer (drain region) DR provided on a top surface (first surface) side of the SiC substrate 1S, the channel layer CH provided on the n-type drift layer DR in the cell region CEL, and the n-type source region SR provided on the channel layer CH. drift layer DR is an n-type, the channel layer CH is a p-type, the source region SR is an n-type. These semiconductor regions are made of SiC, p-type semiconductor regions have a p-type impurity, n-type semiconductor regions have an n-type impurity. Further, these semiconductor regions, as described later, are formed of an epitaxial layer of n-type or p-type.

In addition, the p-type buried region PJTE is provided in the surface portion of a second epitaxial layer EP2 on the cell region CEL side of the peripheral region TER. The p-type buried region PJTE is the p-type having an impurity density lower than that of the channel layer CH and an impurity density lower than that of the body contact region BC. The p-type buried region PJTE is formed to relax an electric field between the cell region CEL and the peripheral region TER.

Then, in the semiconductor device according to the first embodiment, there is the trench TR that penetrates the n-type source region SR and the channel layer CH and reaches the n-type drift layer DR in the cell region CEL. In addition, the semiconductor device has the gate electrode GE disposed in the trench TR via the gate dielectric film GI.

Further, there is the other end on the opposite side to one end portion of the n-type source region SR in contact with the trench TR. At the other end, the contact hole CNT reaching the channel layer CH is provided. Then, a part of a bottom surface of the contact hole CNT, the body contact region BC is formed. The body contact region BC is the p-type having an impurity density higher than that of the channel layer CH, and is formed to secure an ohmic contact between the source electrode SE and the channel layer CH.

Further, so as to cover the gate electrode GE, the interlayer insulating film IL1 is provided. The interlayer insulating film IL1 is made of an insulating film such as a silicon oxide film. Then, inside the interlayer insulating film IL1 and the contact hole CNT, the source electrode SE is provided. The source electrode SE is formed of a conductive film, for example, an aluminum (Al) film. Incidentally, among the source electrode SE, a plug (via) a portion located inside the contact hole CNT, there is a case where the portion extending on the interlayer insulating film IL1 is regarded as wiring. The source electrode SE is electrically connected to the body contact region BC and the n-type source region SR. The surface protective film PAS made of an insulating film is formed on the source electrode SE. Incidentally, the bottom surface of the SiC substrate 1S (second surface) side, the drain electrode DE is formed.

Here, in the first embodiment, the n-type drift layer DR is constituted by a laminated portion of a first epitaxial layer EP1 and the second epitaxial layer EP2 on it, a boundary portion between the first epitaxial layer EP1 and the second epitaxial layer EP2, the p-type first semiconductor region PT1 is provided in the cell region CEL. The p-type first semiconductor region PT1 (field relaxation region) is a position deeper than a bottom surface of the trench TR, having an impurity of a conductivity type opposite to the n-type drift layer DR, and located in the middle of the n-type drift layer DR. That is, the p-type first semiconductor region PT1 is located between the bottom surface of the trench TR and the drain electrode DE. Thus, by providing the p-type first semiconductor region PT1, it is possible to relax the electric field applied to the gate dielectric film GI, it is possible to improve the withstand voltage of the semiconductor device according to the first embodiment.

Further, the peripheral region TER, the p-type second semiconductor region PT2 is provided. Here, the p-type second semiconductor region PT2 has, for example, an impurity of a conductivity type opposite to the n-type drift layer DR at a same position as the p-type first semiconductor region PT1, and is formed at the same impurity density as that of the p-type first semiconductor region PT1. In other words, the p-type second semiconductor region PT2 is located between the first epitaxial layer EP1 and the second epitaxial layer EP2, and is formed in the same layer as the p-type first semiconductor region PT1. For example, impure material density of the p-type second semiconductor area PT2 is preferably a range of 5×10¹⁷ cm⁻³ to 2×10¹⁹ cm⁻³ and is most preferably a range of 2×10¹⁸ cm⁻³ to 7×10¹⁸ cm⁻³.

A width of the p-type second semiconductor region PT2 of the peripheral region TER is formed smaller than a width of the p-type first semiconductor region PT1 of the cell region CEL. Here, the width of the p-type first semiconductor region PT1, refers to a distance W1 between PN borders defined by the p-type first semiconductor region PT1 and the n-type drift layer DR. Further, the width of the p-type second semiconductor region PT2, refers to a distance W2 between PN borders defined by the p-type second semiconductor region PT2 and the n-type drift layer DR. For example, the width of the p-type second semiconductor region PT2 is about a half of the width of the p-type first semiconductor region PT1.

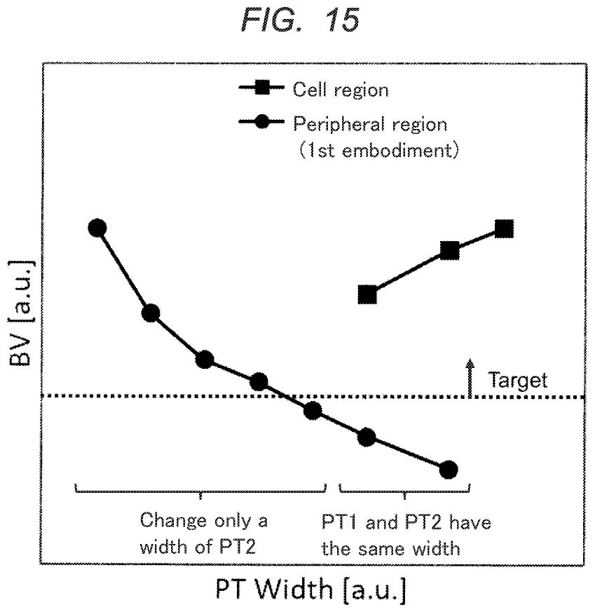

More specifically, for example, the width of the p-type first semiconductor region PT1 in the cell region CEL is 1 μm, the width of the p-type second semiconductor region PT2 in the peripheral region TER is 0.5 μm. The width of the p-type first semiconductor region PT1 is preferably in the range of 0.5 μm to 2 μm, and the width of the p-type second semiconductor region PT2 is preferably in the range of 0.2 μm to 0.6 μm. Further, the ratio of the width of the p-type second semiconductor region PT2 to the width of the p-type first semiconductor region PT1 is preferably in the range of 0.2 to 0.8, and is most preferably 0.5 or less (FIG. 15).

In other words, a pitch of the p-type second semiconductor region PT2 of the peripheral region TER is formed smaller than a pitch of the p-type first semiconductor region PT1 of the cell region CEL. Here, the pitch of the p-type first semiconductor region PT1, refers to a distance P1 defined by distance between a plurality of adjacent p-type first semiconductor region PT1. Further, the pitch of the p-type second semiconductor region PT2, refers to a distance P2 defined by distance between a plurality of adjacent p-type second semiconductor region PT2. For example, the pitch of the p-type first semiconductor region PT1 of the cell region CEL is 2 μm, the pitch of the p-type second semiconductor region PT2 of the peripheral region TER is 1 μm. The pitch of the p-type first semiconductor region PT1 may be 1 μm˜4 μm, the pitch of the p-type second semiconductor region PT2 may be 0.4 μm˜1.2 μm.

FIG. 2 is a plan view of main portion of the semiconductor device according to the first embodiment in the A-A line shown in FIG. 1. Further, a plan view showing a relationship between the p-type first semiconductor region PT1, the p-type second semiconductor region PT2, and the trench TR shown in FIG. 3.

As shown in FIG. 2, when a direction from the cell region CEL to the peripheral region TER is X direction, the planar shape of the gate electrode GE is a rectangular shape having a long side in Y direction, which is perpendicular to X direction. Planar shape of the trench TR is a rectangular shape having a long side along Y direction. The n-type source region SR is arranged on both sides of the trench TR. Planar shape of the n-type source region SR is a rectangular shape having a long side along Y direction. The body contact region BC is disposed outside the n-type source region SR. Planar shape of the body contact region BC is a rectangular shape having a long side along Y direction.

The source electrode SE is spread so as to extend above the gate electrode GE as shown in FIG. 3. Further, although not displayed in the cross section shown in FIG. 3, on a chip end portion extending in a depth direction of the gate electrode GE, via a contact hole (plug, via) (not shown), a gate wiring GL and the gate pad GPD shown in FIG. 1 are arranged. The gate wiring GL or the gate pad GPD can be constituted by a conductive film having the same layer as the source electrode SE. Then, the outside surrounding the gate wiring GL, a source wiring SL connected to the source pad SPD is provided (FIG. 1).

Then, as described above, the p-type semiconductor region (PT1, PT2), similarly to the trench TR and the gate electrode GE, and extends in Y direction (in FIG. 3, the depth direction of the drawing).

### Operation

In the semiconductor device (transistor) according to the first embodiment, when a gate voltage equal to or higher than a threshold voltage is applied to the gate electrode GE, an inversion layer is formed in the channel layer (p-type) CH in contact with the side surface of the trench TR. Then, the n-type source region SR and the n-type drift layer DR will be electrically connected by an inverting layer, when there is a potential difference between the n-type source region SR and the n-type drift layer DR, n-type source region SR through the inverting layer electrons flow to the n-type drift layer DR. In other words, current flow from the n-type drift layer DR through the inversion layer to the n-type source region SR. In this manner, the transistor can be turned on.

On the other hand, when a voltage smaller than the threshold voltage is applied to the gate electrode GE, the inversion layer formed in the channel layer CH disappears, the n-type source region SR and the n-type drift layer DR becomes non-conductive. In this manner, the transistor can be turned off.

As described above, by changing the gate voltage applied to the gate electrode GE of the transistor, it performs on/off operation of the transistor.

### Manufacturing Method

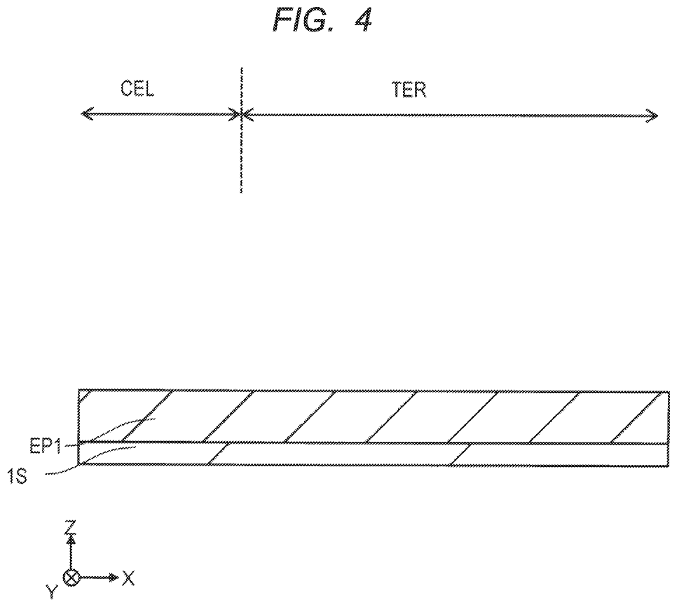

Next, referring to FIGS. 4 to 12, manufacturing method of the semiconductor device according to the first embodiment will be explained, and a configuration of the semiconductor device will be clarified. FIGS. 4 to 12 are cross-sectional view corresponding to the A-A line in FIG. 2 and showing the manufacturing process of the semiconductor device according to the first embodiment.

Manufacturing method of the semiconductor device according to the first embodiment includes (1) forming the first epitaxial layer EP1, (2) forming the p-type first semiconductor region PT1 and the p-type second semiconductor region PT2, (3) forming the second epitaxial layer EP2, (4) forming the channel layer CH, (5) forming the p-type buried region PJTE, (6) forming the n-type source region SR, (7) forming the body contact region BC, (8) forming the trench TR and the gate electrode GE, and (9) forming the source electrode SE and the surface protective film PAS.

### (1) Forming the First Epitaxial Layer EP1

As shown in FIG. 4, the SiC substrate in which the first epitaxial layer EP1 is formed (semiconductor substrate made of SiC, a wafer) 1S is prepared.

The epitaxial layers can be formed on the SiC substrate 1S in the following manner. For example, the first epitaxial layer EP1 is formed by growing an epitaxial layer (n-type epitaxial layer) made of SiC on the SiC substrate 1S introducing an n-type impurity such as nitrogen (N) or phosphorus (P).

### (2) Forming the P-Type First Semiconductor Region PT1 and the P-Type Second Semiconductor Region PT2

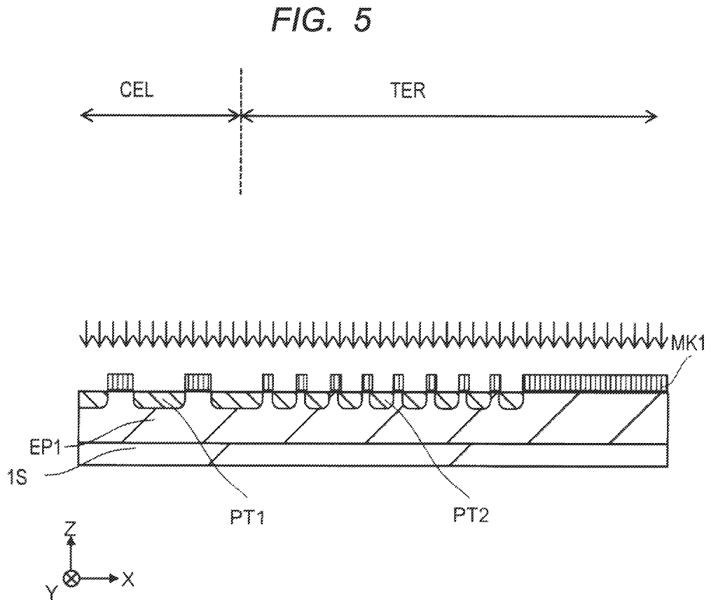

Next, as shown in FIG. 5, the p-type first semiconductor region PT1 of the cell region CEL and the p-type second semiconductor region PT2 of the peripheral region TER are formed. For example, using a photolithography technique and an etching technique, on the first epitaxial layer EP1, to form a mask film MK1 having an opening in the p-type first semiconductor region PT1 of the cell region CEL and a formed region of the p-type second semiconductor region PT2 of the peripheral region TER. As the mask film MK1, for example, the silicon oxide film can be used. Here, the width of the p-type first semiconductor region PT1 of the cell region CEL is opened larger than the width of the p-type second semiconductor region PT2 of the peripheral region TER. More specifically, for example, the width of the p-type first semiconductor region PT1 of the cell region CEL is 1-2 μm, and the width of the p-type second semiconductor region PT2 of the peripheral region TER is 0.2-0.6 μm.

Next, using the mask film MK1 as a mask, p-type impurity ions such as aluminum (Al) or boron (B) are implanted into a surface portion of the first epitaxial layer EP1 to form the p-type first semiconductor region PT1 of the cell region CEL and the p-type second semiconductor region PT2 of the peripheral region TER.

The P-type second semiconductor region PT2 of the peripheral region TER and the p-type first semiconductor region PT1 of the cell region CEL, as shown in FIG. 2, extend in Y direction.

### (3) Forming the Second Epitaxial Layer EP2

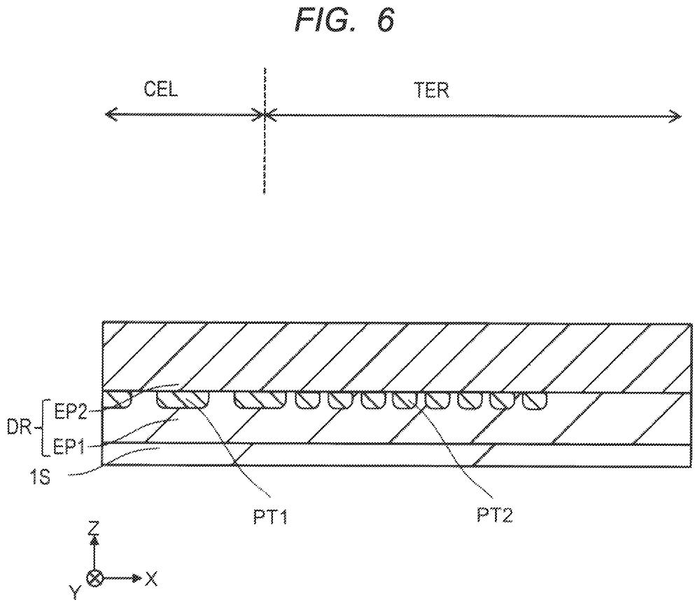

Next, as shown in FIG. 6, the second epitaxial layer EP2 is formed. For example, an epitaxial layer (n-type epitaxial layer) made of SiC is grown on the first epitaxial layer EP1, the p-type first semiconductor region PT1 of the cell region CEL, and the p-type second semiconductor region PT2 of the peripheral region TER introducing an n-type impurity such as nitrogen (N) or phosphorus (P), respectively, to form the second epitaxial layer EP2. Thus, the first epitaxial layer EP1, the n-type drift layer DR made of a laminate of the second epitaxial layer EP2 is formed. Then, inside the n-type drift layer DR, the p-type first semiconductor region PT1 of the cell region CEL and the p-type second semiconductor region PT2 of the peripheral region TER are provided. Specifically, the p-type first semiconductor region PT1 of the cell region CEL and the p-type second semiconductor region PT2 of the peripheral region TER are provided near the boundary between the first epitaxial layer EP1 and the second epitaxial layer EP2. In other words, the p-type first semiconductor region PT1 and the p-type second semiconductor region PT2 are formed at the same position having the same distance from the surface of the second epitaxial layer EP2. Also, it is the same about a distance from the top surface (first surface) of the SiC substrate.

### (4) Forming the Channel Layer CH

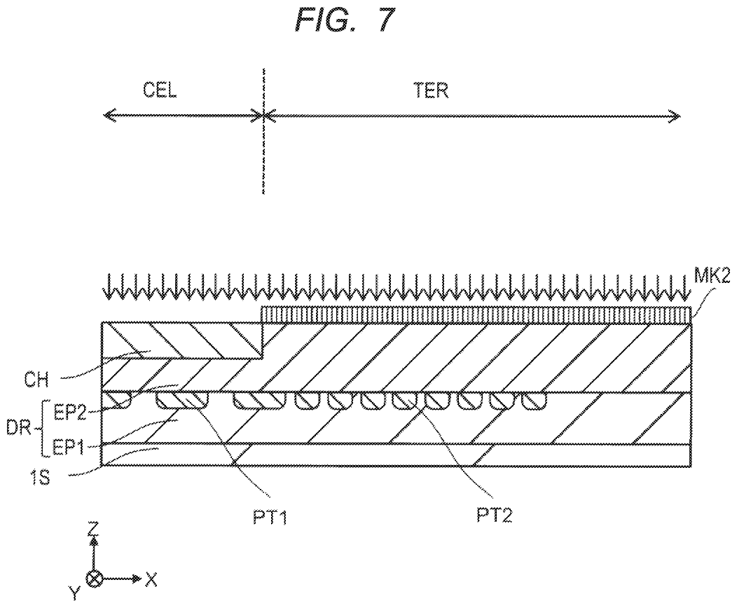

Next, as shown in FIG. 7, with a mask film MK2 as a mask, p-type impurity ions such as aluminum (Al) or boron (B) are implanted into a surface portion of the second epitaxial layer EP2 to form a semiconductor region serving as the channel layer CH.

### (5) Forming the P-Type Buried Region PJTE

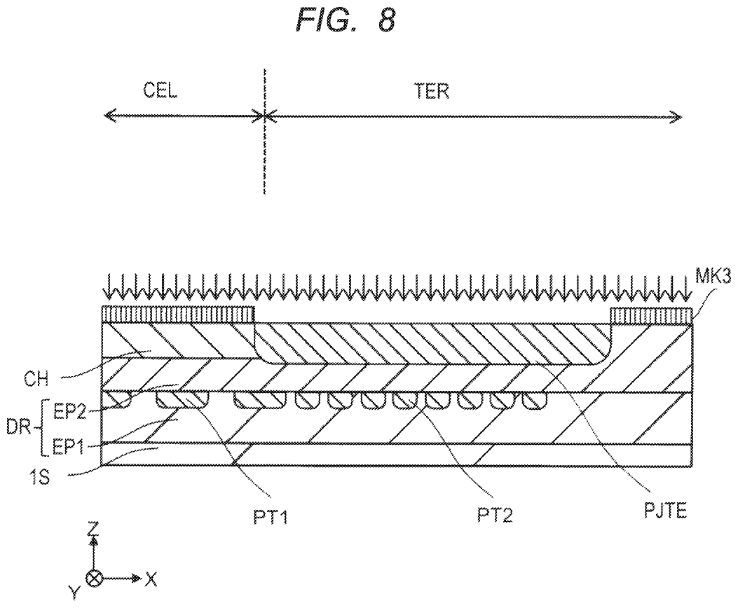

Next, as shown in FIG. 8, using a mask film MK3 as a mask, p-type impurity ions such as aluminum (Al) or boron (B) are implanted into a surface portion of the peripheral region TER on the second epitaxial layer EP2 to form the p-type buried region PJTE.

### (6) Forming the N-Type Source Region SR

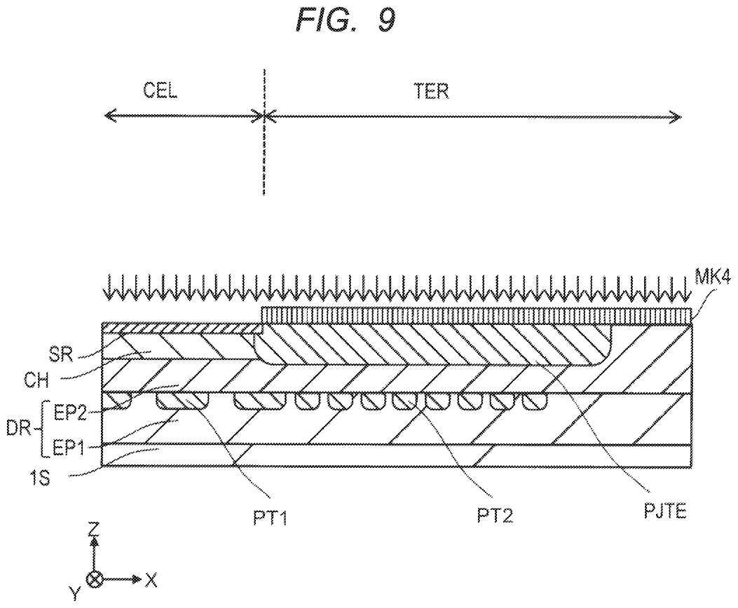

Next, as shown in FIG. 9, using a mask film MK4 as a mask, n-type impurity ions such as nitrogen (N) or phosphorus (P) are implanted into a surface portion of the second epitaxial layer EP2 to form a semiconductor region serving as the n-type source region SR.

### (7) Forming the Body Contact Region BC

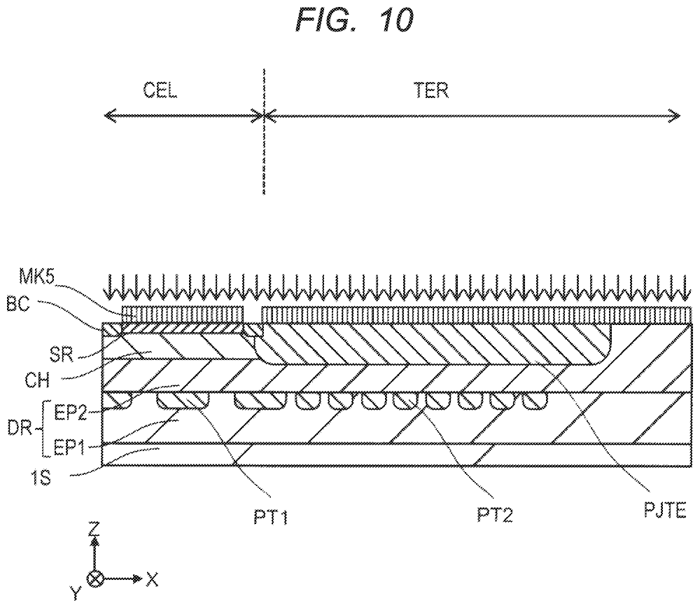

Next, as shown in FIG. 10, a semiconductor region corresponding to the body contact region BC is formed by implanting p-type impurity ions such as aluminum (Al) or boron (B) into a surface portion of the second epitaxial layer EP2 using a mask film MK5 as a mask. Here, a density of the p-type impurity in the body contact region BC is higher than a density of the p-type impurity in the channel layer CH.

### (8) Forming the Trench TR and the Gate Electrode GE

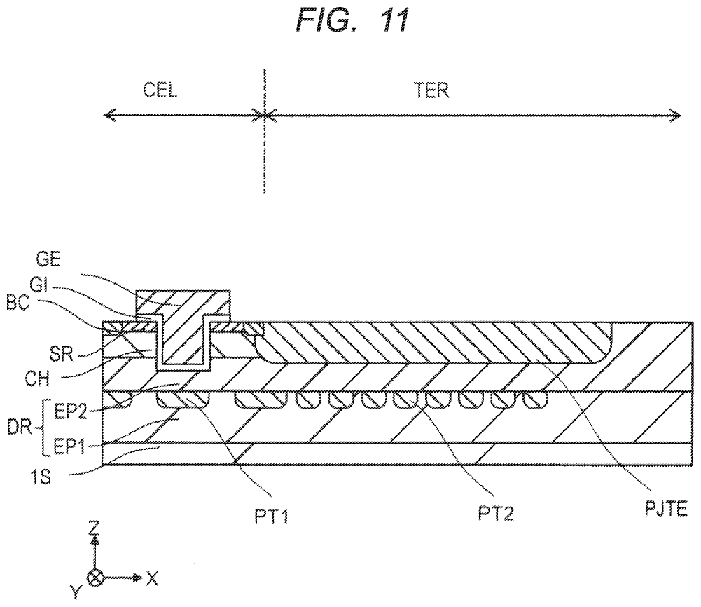

Then, as shown in FIG. 11, in the cell region CEL, through the n-type source region SR and the channel layer CH, to form the trench TR reaching the second epitaxial layer EP2 (see FIG. 2).

For example, using photolithography and etching techniques, on the n-type source region SR, to form a hard mask (not shown) having an opening in a formation region of the trench TR. Next, using this hard mask as a mask, the n-type source region SR, by etching an upper portion of the channel layer CH and the second epitaxial layer EP2, to form the trench TR. Next, the hard mask is then removed. In side surfaces of the trench TR, the second epitaxial layer EP2, the channel layer CH and the n-type source region SR are exposed in this order from a bottom of it. Further, in the bottom surface of the trench TR, the second epitaxial layer EP2 is exposed. Here, the p-type first semiconductor region PT1 of the cell region CEL and the p-type second semiconductor region PT2 of the peripheral region TER are located deeper than the bottom surface of the trench TR.

Next, the gate dielectric film GI is formed over each of the trench TR, the channel layer CH, and the n-type source region SR. For example, the silicon oxide film is formed as the gate dielectric film GI by an ALD (Atomic Layer Deposition) method or the like. Further, by thermally oxidizing the epitaxial layer exposed in the trench TR, it may be formed the gate dielectric film GI. The gate dielectric film GI is made of, for example, silicon oxide. Note that, the material of the gate dielectric film GI is not limited to silicon oxide, and the material may be aluminum oxide or hafnium oxide. Aluminum oxide and hafnium oxide have advantages of high dielectric constant and high current driving force.

In addition, the gate electrode GE is formed so as to dispose on the gate dielectric film GI and to embed the trench TR. For example, as a conductive film for the gate electrode GE, a polysilicon film is deposited by a CVD (Chemical Vapor Deposition) method or the like. Next, on the conductive film, a photoresist film (not shown) covering a formation region of the gate electrode GE is formed. And the conductive film is etched by using the photoresist film as a mask. Thus, to form the gate electrode GE. During this etching, it may be etched the gate dielectric film GI exposed on both sides of the gate electrode GE.

### (9) Forming the Source Electrode SE and the Surface Protective Film PAS

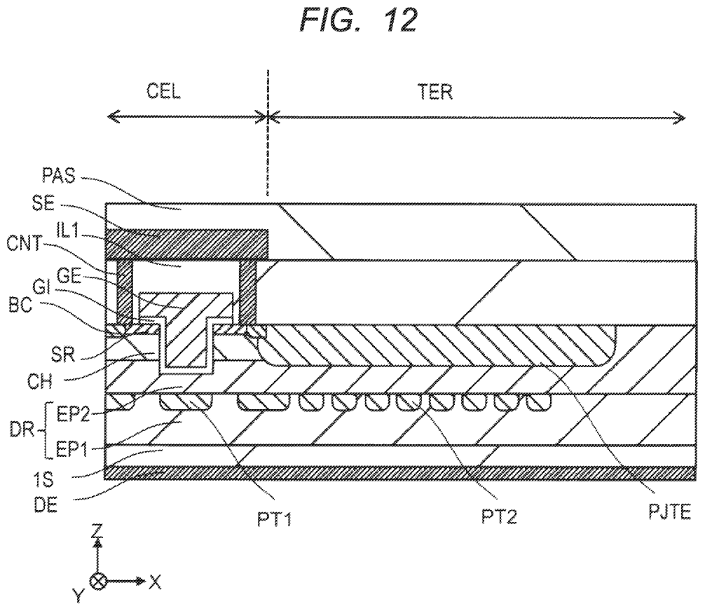

Then, as shown in FIG. 12, to form the interlayer insulating film IL1 covering the gate electrode GE, to form the contact hole CNT.

For example, The silicon oxide film is deposited as the interlayer insulating film IL1 by a CVD method on each of the body contact region BC exposed from a bottom surface of the contact hole CNT, the n-type source region SR, and the gate electrode GE. Next, on the interlayer insulating film IL1, a photoresist film (not shown) having an opening is formed on the body contact region BC and a part of the n-type source region SR on both sides thereof. Next, the contact hole CNT is formed by etching the interlayer insulating film IL1 using this photoresist film as a mask. The body contact region BC and a part of the n-type source region SR are exposed below the contact hole CNT. Incidentally, the interlayer insulating film IL1 over the gate electrode GE, which is not shown in the cross section shown in FIG. 12, is removed, and a contact hole (not shown) is formed over the gate electrode GE.

Next, the source electrode SE is formed. For example, each of an inner of the contact hole CNT and on the interlayer insulating film IL1, as a barrier metal film (not shown), a TiN film is formed by a sputtering method or the like. Next, on the barrier metal film (not shown), as a conductive film, an Al film is formed by a sputtering method or the like. Next, by patterning the laminated film of the barrier metal film (not shown) and the conductive film (Al film), to form the source electrode SE. At this time, the gate wiring GL and the gate pad GPD, which is not shown in the cross section shown in FIG. 12, is formed (see FIG. 1). Note that, after forming a silicide film, the source electrode SE or the like may be formed on the body contact region BC (inner wall of the contact hole CNT).

Next, the surface protective film PAS is formed so as to cover the source electrode SE, the gate wiring GL, and the gate pad GPD. For example, a silicon oxide film is deposited as the surface protective film PAS on the source electrode SE or the like by a CVD method or the like. Then, by patterning the surface protective film PAS, a partial region of the source electrode SE and a partial region of the gate pad GPD are exposed. The exposed portion becomes as an external connection region (pad).

Next, the bottom surface (second surface) opposite to the main surface of the SiC substrate 1S is used as an upper surface, and the bottom surface of the SiC substrate 1S is ground to thin the SiC substrate 1S.

Next, on the bottom surface of the SiC substrate 1S, to form the drain electrode DE. For example, the bottom surface of the SiC substrate 1S is used as the upper surface, to form a metal film. For example, Ti film, Ni film and Au film are formed by such sequential sputtering method. Thus, the drain electrode DE made of the metal film can be formed. Note that the silicide film may be formed between the metallic film and the SiC substrate 1S. Thereafter, the SiC substrate (wafer) 1S having a plurality of chip regions is cut out for each chip region.

Through the above steps, the semiconductor device of the first embodiment can be formed.

In the above step, the n-type drift layer DR is constituted by a laminated body of the first epitaxial layer EP1 and the second epitaxial layer EP2. It may be also provided , the n-type drift layer DR is as a single epitaxial layer EP and the p-type first semiconductor region PT1 of the cell region CEL and the p-type second semiconductor region PT2 of the peripheral region TER are provided by implanting deeply ion implantation.

### Effect of the First Embodiment

Thus, according to the first embodiment, provided the p-type first semiconductor region PT1 of the cell region CEL and the p-type second semiconductor region PT2 of the peripheral region TER, further The width of the p-type second semiconductor region PT2 of the peripheral region TER is arranged smaller than the width of the p-type first semiconductor region PT1 of the cell region CEL. Thus, an electric field concentration to the gate dielectric film GI is relaxed, while maintaining the withstand voltage of the cell region CEL, it is possible to suppress the local electric field concentration at the peripheral region TER, thereby suppressing the withstand voltage degradation. Hereinafter, effects of the first embodiment will be described in detail with reference to a comparative example. Hear, the comparative example is one of internal examination technologies, not prior art.

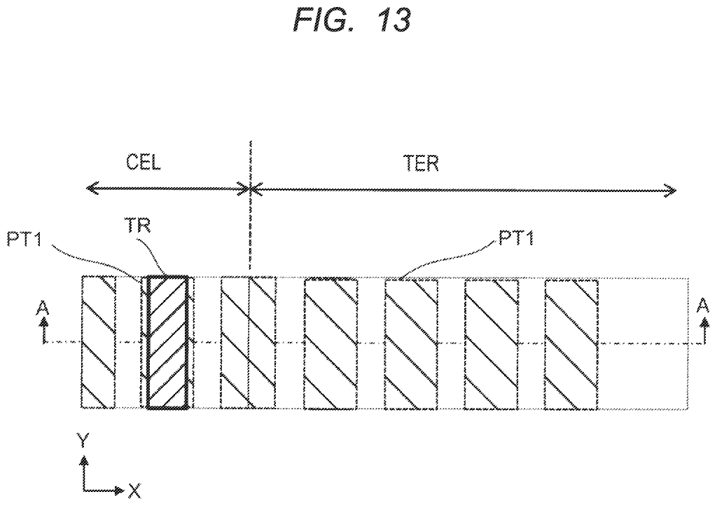

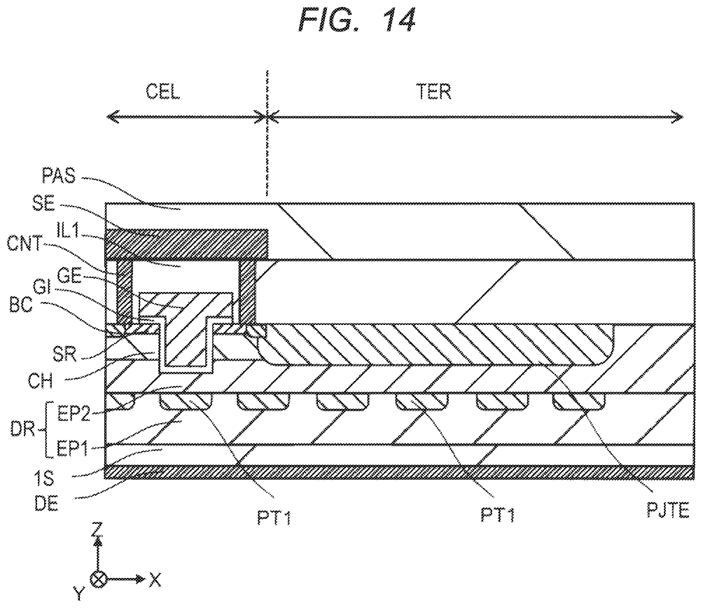

FIG. 13 is a plan view showing a relationship between the trench TR and the p-type first semiconductor region PT1 of the comparative example. FIG. 14 is a cross-sectional view of the comparative example. The p-type first semiconductor region PT1 of the cell region CEL is arranged with the same width in the cell region CEL and the peripheral region TER.

FIG. 15 is a diagram showing a relationship between a withstand voltage of the semiconductor device according to the comparative example and the first embodiment and the width of the p-type first semiconductor region PT1 and the p-type second semiconductor region PT2. Horizontal axis shows the width of the p-type first semiconductor region PT1 in the cell region CEL and the width of the p-type second semiconductor region PT2 in the peripheral region TER, and vertical axis shows the withstand voltage (BVoff, [a.u.]). Incidentally, the first embodiment as an exemplary, the density of p-type imputes of the p-type first semiconductor region PT1 and p-type second semiconductor region PT2 is 2×10¹⁸ cm⁻³ to 7×10¹⁸ cm⁻³.

As shown in FIG. 15, when the p-type first semiconductor region PT1 and the p-type second semiconductor region PT2 is the same width, it can be seen that a withstand voltage in the peripheral region TER is lower than a withstand voltage in the cell region CEL. In the case of the comparative example shown in FIG. 13 and FIG. 14, the cell region CEL satisfies a target withstand voltage, but the peripheral region TER is not obtained sufficient the target withstand voltage indicated by the broken line. However, in the first embodiment, by setting the p-type first semiconductor region PT1 and the p-type second semiconductor region PT2 to have a different width and making the width of the p-type second semiconductor region PT2 smaller than the width of the p-type first semiconductor region PT1, it is understand that the target withstand voltage can be satisfied in the peripheral region TER.

Thus, in the semiconductor device according to the first embodiment, while maintaining the withstand voltage of the cell region CEL, by reducing the width of the p-type second semiconductor region PT2 in the peripheral region TER, the peripheral region TER can also satisfy the target withstand voltage.

Incidentally, the width of the p-type second semiconductor region PT2 being smaller than the width of the p-type first semiconductor region PT1 relaxes the electric field of the gate insulating film GI because the p-type first semiconductor region PT1 is not depleted during bias application. On the other hand, the p-type second semiconductor region PT2 is preferable from the viewpoint of preventing the withstand voltage of the peripheral region TER from being lowered by depleting it. For example, a ratio of the width of the p-type second semiconductor region PT2 to the width of the p-type first semiconductor region PT1 is preferably 0.2 to 0.8, most preferably 0.5 or less.

### Second Embodiment

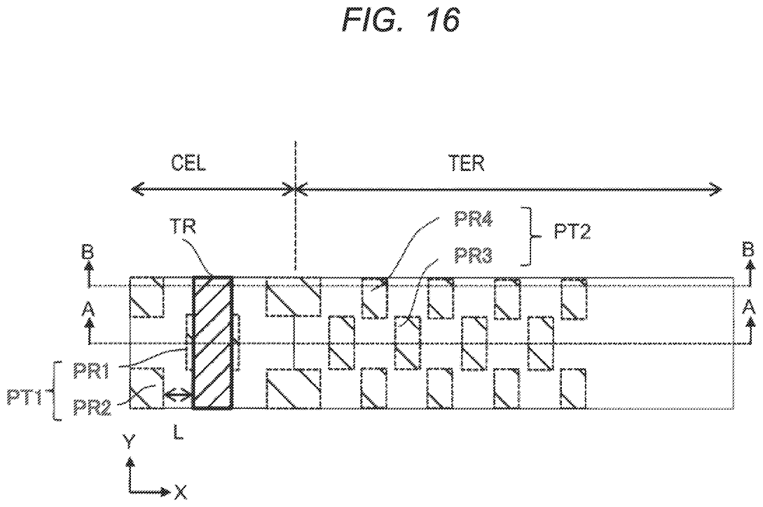

FIG. 16 is a plan view of a main portion diagram showing an exemplary configuration of a semiconductor device according to a second embodiment. As shown in FIG. 16, the p-type first semiconductor region PT1 in the cell region CEL includes a first region PR1 located below the trench TR and a second region PR2 located at a distance L in X direction from the trench TR. And the first region PR1 and the second region PR2 are thinned out in Y direction in which the trenches extend, and are arranged in a staggered manner.

Similarly, the p-type second semiconductor region PT2 in the peripheral region TER includes a third region PR3 and a fourth region PR4. And the third region PR3 and the fourth region PR4 are thinned out in Y direction in which the trenches extend, and are arranged in a staggered manner.

In plan view, the p-type second semiconductor region PT2 has a plurality of third region PR3 arranged at a constant interval in Y direction and a plurality of fourth region PR4 arranged at a constant interval in X direction orthogonal to Y direction. And the third region PR3 and the fourth region PR4 are arranged such that a repetition pitch of the third region PR3 and a repetition pitch of the fourth region PR4 are shifted by half in Y direction.

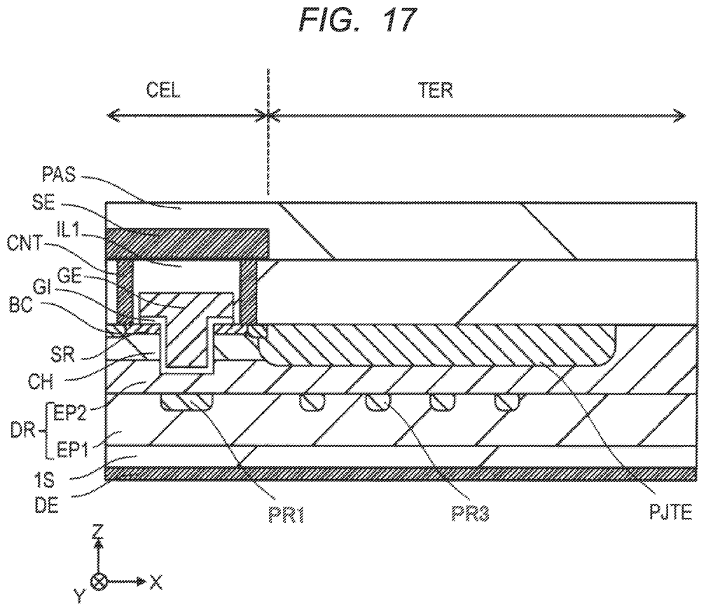

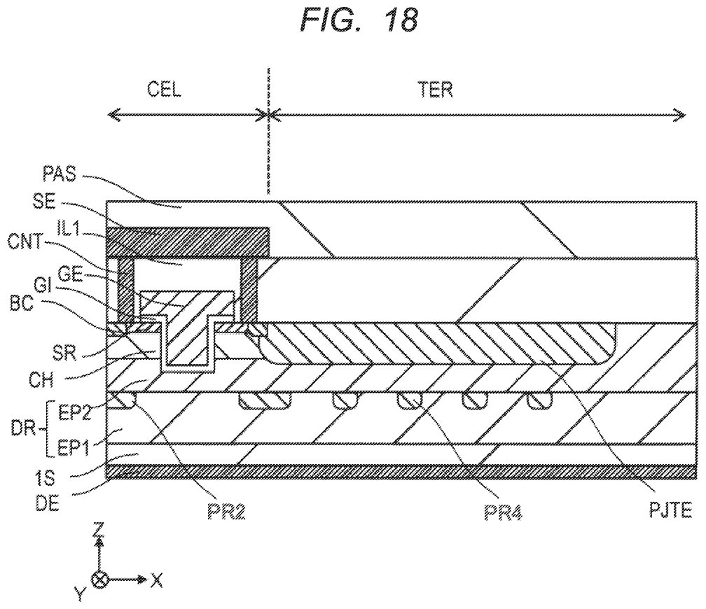

FIG. 17 is a cross-sectional view in A-A line shown in FIG. 16, and FIG. 18 is a cross-sectional view in B-B line shown in FIG. 16. As shown in FIGS. 17 and 18, of the p-type first semiconductor region PT1 at a boundary between the first epitaxial layer EP1 and the second epitaxial layer EP2, a region located below the trench TR is defined as the “first region PR1” , and a region located below the body contact region BC (that is, on a side of the trench TR) is referred to as the “second region PR2”.

As shown in FIGS. 17 and 18, the n-type drift layer DR is constituted by a laminated portion of the first epitaxial layer EP1 and the second epitaxial layer EP2 on this. The first region PR1 and the second region PR2 are provided at the border between the first epitaxial layer EP1 and the second epitaxial layer EP2. The first region PR1 and the second region PR2 are at a position deeper than the bottom surface of the trench TR, has an impurity type opposite to the n-type drift layer DR, and located in the middle of the n-type drift layer DR. Thus, by providing the first region PR1 and the second region PR2, it is possible to relax the electric field applied to the gate dielectric film GI, and it is possible to improve the withstand voltage of the semiconductor device according to the second embodiment.

The first region PR1 is formed in the n-type drift layer DR below the trench TR at a position overlapping the forming region of the trench in plan view, and has an impurity type opposite to the n-type drift layer DR. And, the second region PR2 is formed in the n-type drift layer DR below the trench TR, separated by the distance L from a forming region of the trench TR in plan view, and having an impurity type opposite to the n-type drift layer DR.

And, the first region PR1 is arranged at a predetermined interval along the trench TR. In other words, the p-type first semiconductor region PT1 is disposed in the extending direction of the trench TR (the gate electrode GE) and part of thereof is thinned out. A region where the first region PR1 is thinned out becomes an interval.

Thus, by thinning the p-type first semiconductor region PT1, it is possible to secure a current path, and it is possible to reduce the on-resistance.

Then, the transistor shown in FIG. 16 is repeatedly arranged in a plan view.

### Effect of the Second Embodiment

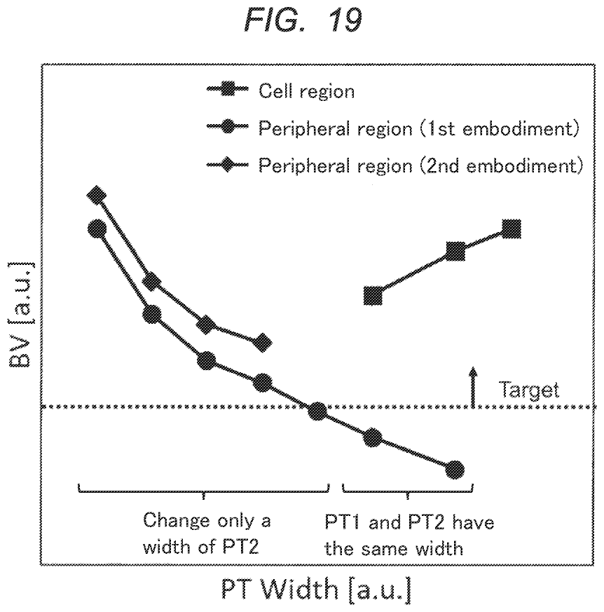

As shown in FIG. 19, when the p-type first semiconductor region PT1 and the p-type second semiconductor region PT2 is the same width, it can be seen that a withstand voltage of the peripheral region TER is lower than a withstand voltage of the cell region CEL. However, in the second embodiment, the p-type second semiconductor region PT2 of the peripheral region TER is composed of the third region PR3 and the fourth region PR4, and the p-type second semiconductor region PT2 is arranged in a staggered manner. As a result, the target withstand voltage can be satisfied in the peripheral region TER as compared with the first embodiment.

Therefore, in the semiconductor device of the second embodiment, while maintaining the withstand voltage of the cell region CEL, by providing the p-type second semiconductor region PT2 having a the third region PR3 and the fourth region PR4 in the peripheral region TER, it is possible to suppress a deterioration of the withstand voltage in the peripheral region TER.

### Modified Example

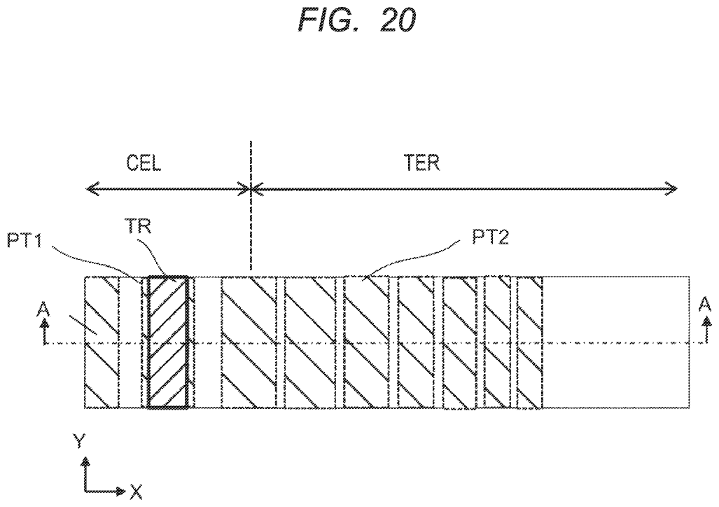

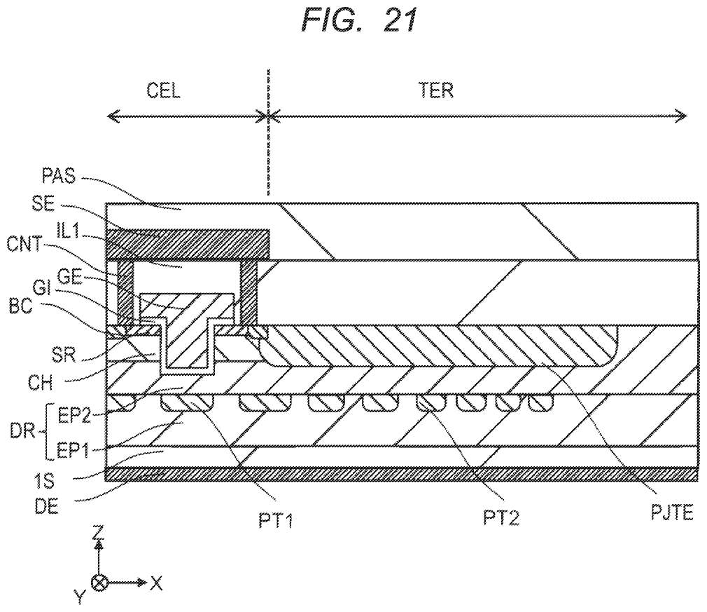

FIG. 20 is a plan view of a main portion diagram showing an exemplary configuration of a semiconductor device according to a modified example of the first embodiment. FIG. 21 is a cross-sectional view illustrating an exemplary configuration of the semiconductor device according to the modified example of the first embodiment in A-A line shown in FIG. 20.

As shown in FIG. 21, the n-type drift layer DR is provided by a laminated portion of the first epitaxial layer EP1 and the second epitaxial layer EP2 on this, and the p-type first semiconductor region PT1 is provided in a boundary between the first epitaxial layer EP1 and the second epitaxial layer EP2. The p-type first semiconductor region PT1 is at a position deeper than the bottom surface of the trench TR, has an impurity type opposite to the n-type drift layer DR, located in a middle of the n-type drift layer DR. Thus, by providing the p-type first semiconductor region PT1, it is possible to relax an electric field applied to the gate dielectric film GI, it is possible to improve the withstand voltage of the semiconductor device according to the second embodiment.

Furthermore, as shown in FIGS. 20 and 21, The width of the p-type second semiconductor region PT2 of the peripheral region TER is gradually smaller than the width of the p-type first semiconductor region PT1 of the cell region CEL in the direction away from the cell region CEL. That is, the width of the p-type second semiconductor region PT2 of the peripheral region TER is gradually reduced in the direction toward an outer peripheral edge of the semiconductor device (semiconductor chip) located on the opposite side of the cell region CEL.

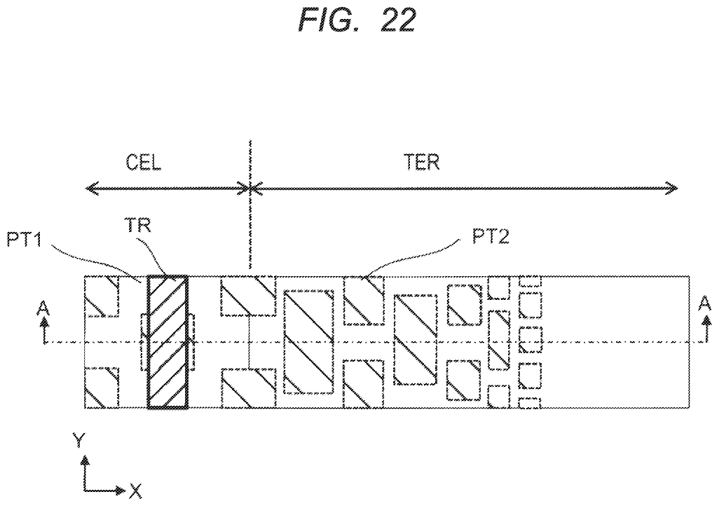

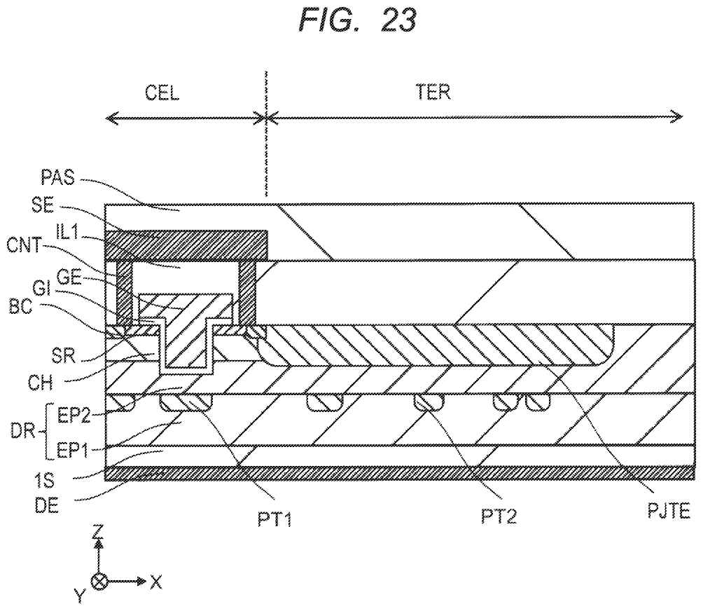

FIG. 22 is a plan view illustrating an exemplary configuration of the semiconductor device according to the modified example of the present second embodiment. FIG. 23 is a cross-sectional view illustrating an exemplary configuration of the semiconductor device according to the modified example of second embodiment in A-A line shown in FIG. 22. As shown in FIG. 23, the n-type drift layer DR is provided by a laminated portion of the first epitaxial layer EP1 and the second epitaxial layer EP2 on this, and the p-type first semiconductor region PT1 is provided in a boundary between the first epitaxial layer EP1 and the second epitaxial layer EP2. The p-type first semiconductor region PT1 is at a position deeper than the bottom surface of the trench TR, has an impurity type opposite to the n-type drift layer DR, located in the middle of the n-type drift layer DR. Thus, by providing the p-type first semiconductor region PT1, it is possible to relax the electric field applied to the gate dielectric film GI, it is possible to improve the withstand voltage of the semiconductor device according to the second embodiment.

Furthermore, as shown in FIGS. 22 and 23, the width of the p-type second semiconductor region PT2 of the peripheral region TER is gradually smaller than the width of the p-type first semiconductor region PT1 of the cell region CEL in the direction away from the cell region CEL. That is, the width of the p-type second semiconductor region PT2 of the peripheral region TER is gradually reduced in the direction toward the outer peripheral edge of the semiconductor device (semiconductor chip) located on the opposite side of the cell region CEL. The interval between the adjacent p-type second semiconductor regions PT2 is also reduced from the cell region to the peripheral region.

### Effect of the Modified Example

As shown in FIG. 19, when the p-type first semiconductor region PT1 and the p-type second semiconductor region PT2 is the same width, it can be seen that a withstand voltage of the peripheral region TER is lower than a withstand voltage of the cell region CEL. However, in the modified example, by gradually reducing the width of the p-type second semiconductor region PT2 of the peripheral region TER in a direction toward the outer peripheral edge from the cell region CEL, to suppress a sharp electric field gradient, even the peripheral region TER it can be seen that satisfies the withstand voltage of the target.

Thus, in the semiconductor device of the modified example, it is possible to suppress the withstand voltage degradation of the peripheral region TER while maintaining the withstand voltage of the cell region CEL.

Although the invention made by the present inventor has been specifically described based on the embodiment, the present invention is not limited to the as described above embodiment, and it is needless to say that various modifications can be made without departing from the gist thereof.

In addition, even when a specific numerical value example is described, it may be a numerical value exceeding the specific numerical value, or may be a numerical value less than the specific numerical value, except when it is theoretically obviously limited to the numerical value. In addition, the component means “B containing A as a main component” or the like, and the mode containing other components is not excluded.

What is claimed is:

1. A manufacturing method of a semiconductor device having a cell region and a peripheral region surrounding a circumference of the cell region, comprising the steps of:
(a) forming a drift layer over a semiconductor substrate being made of silicon carbide;
(b) forming a channel layer over the drift layer;
(c) forming a source region over the channel layer;
(d) forming a trench penetrating the channel layer to reach the drift layer and contacting the source region;
(e) forming a gate dielectric film over an inner wall of the trench;
(f) forming a gate electrode over the trench so as to embed in trench;
wherein the step of (a) includes the steps of:
(a1) in a position in the drift layer, forming a first semiconductor region in the cell region and forming a second semiconductor region in the peripheral region,
wherein the trench, the first semiconductor region and the second semiconductor region are extended in a first direction in a plan view, and
wherein a width of the first semiconductor region in a second direction intersecting with the first direction is different from a width of the second semiconductor region in the second direction.

2. The manufacturing method of the semiconductor device according to claim 1,
wherein the second semiconductor region is formed in a same layer as the first semiconductor region.

3. The manufacturing method of the semiconductor device according to claim 2,
wherein the drift layer in the step of (a) is formed by forming steps of a first epitaxial layer and a second epitaxial layer.

4. The manufacturing method of the semiconductor device according to claim 3,
wherein the step of (a1) is performed after the forming step of the first epitaxial layer before the forming step of the second semiconductor region.

5. The manufacturing method of the semiconductor device according to claim 2,
wherein the width of the second semiconductor region in the second direction is smaller than the width of the first semiconductor region in the second direction.

6. The manufacturing method of the semiconductor device according to claim 2,
wherein the peripheral region includes a plurality of the second semiconductor region, and
wherein the plurality of the second semiconductor region is disposed at a predetermined interval in the second direction each other.

7. The manufacturing method of the semiconductor device according to claim 6,
wherein the plurality of the second semiconductor region are disposed in a staggered manner being separated from each other in a plan view.
